(19) United States
(12) Patent Application Publication
(10) Pub. No.: US 2012/0069244 A1
(43) Pub. Date: Mar. 22, 2012

(54) METHOD AND CIRCUIT FOR RECOVERING A SYNC SIGNAL FED VIA A CABLE TO A RASTER SCAN DISPLAY DEVICE

(76) Inventor: Joseph Kramer, Mevasseret Zion (IL)

(21) Appl. No.: 13/321,724

(22) PCT Filed: May 16, 2010
(86) PCT No.: PCT/IL2010/000391

§ 371 Date: Nov. 21, 2011

(30) Foreign Application Priority Data
May 21, 2009 (IL) 198868

(51) Int. Cl. H04N 5/08

(52) U.S. Cl. 348/533; 348/525; 348/E05.017

(57) ABSTRACT

In a method and circuit for recovering a sync signal from an input sync signal passing through a cable to a display device, an average value of the input sync signal is obtained during a predetermined time period so as to obtain a sync threshold, which is compared with the input sync signal. A sync signal is output when the input sync signal is greater than the sync threshold.

### FIELD OF THE INVENTION

This invention relates to a sync circuit for a display monitor.

### BACKGROUND OF THE INVENTION

Host devices such as digital computers and games employ display units such as LCDs or cathode ray tubes (CRT) by which the computer or game is monitored. It is commonly required to physically separate the display device from the host devices and this is most typically done using cables that are connected via mating plugs to respective sockets in the electronic device and display monitor. Normally these cables are in the order of four to six feet in length, enabling limited separation of a monitor from a computer or other host device.

There are, however, situations where it is desirable to increase significantly the separation between a host device and display monitor. This may be by virtue of space limitations or because of environmental considerations, the latter sometimes including an inhospitable environment for a host device.

Display monitors include a control circuit that includes horizontal and vertical scan synchronization circuits for controlling the raster scan sweep pattern of the electron beams generated by the display device. The horizontal scan synchronization circuit synchronizes each horizontal sweep of the electron beams with a horizontal sync signal in the received display signal, and generates a distinctive transient voltage signal at the beginning of each horizontal sweep of the electron beams. Likewise, the vertical scan circuit synchronizes each vertical sweep of the electron beams with a vertical sync signal in the received display signal, and generates a distinctive transient voltage signal at the beginning of each vertical sweep of the electron beams for redirecting the electron beams to the start of the display screen.

There is a natural limit to the maximum separation between a raster scan display monitor and a host device that is achievable merely by extending the length of the connecting cable. This is due to the self-capacitance of the cable, which both attenuates and distorts the sync signals required to synchronize horizontal and vertical scanning The effect of attenuation is such that once the sync signals become too small to pass a threshold value, they will not be detected by the control circuit. The effect of distortion is such that the rise time of the sync signal increases, such that it takes longer to pass a given detection threshold. This can result in the sync signal being detected too late. In either case, the display goes blank.

FIGS. 1a and 1b show graphical representations of normal and inverted sync pulses, respectively. The dotted lines depict recovered sync pulses after a short travel in a coaxial or CAT5 cable. The width of the recovered sync pulse is equal to the time between the sync pulse passing a slicing level as it rises and subsequently falls. Thus, when the sync pulse is perfectly square as shown in FIGS. 1a and 1b such that its rise time is substantially zero, the width of the recovered sync pulse is the same as that of the input sync pulse fed to the cable.

FIGS. 2, 3 and 4 show graphically the effect on the sync pulse caused by passing through cables of increasing length. Thus, FIG. 2 shows that after passing through a cable of short length (up to 10 m) the recovered sync pulse is somewhat narrower than normal since its rise time is no longer zero and so by the time it passes the slicing level, the remaining pulse width is reduced. The CMOS slicing level is in the middle of the sync pulse so as to detect the sync pulse when its amplitude is half its maximum value.

FIG. 3 shows that after traveling in a long cable (up to 60m), the sync pulse is both much more distorted and much reduced in amplitude. The distortion manifests itself in that the sync pulse now takes much longer to pass the threshold and the recovered sync pulse is very narrow as sync pulse only just reaches the slicing level.

FIG. 4 shows that after traveling in a very long cable (up to 300m), the sync pulse is both very highly distorted and very much reduced in amplitude, so much so that it does not pass the slicing level and so cannot be recovered.

It would clearly be desirable to permit longer cables to be used, while avoiding the above-mentioned drawbacks.

### SUMMARY OF THE INVENTION

It is therefore an object of this invention to provide a circuit that allows the length of cable connecting a host device and a raster scan display unit to be increased while still allowing the control circuit of the display unit to detect the sync signals.

This object is realized in accordance with an aspect of the invention by a method for recovering a sync signal from an input sync signal passing through a cable to a display device, the method comprising:

obtaining an average value of the input sync signal during a predetermined time period so as to obtain a sync threshold;

comparing the input sync signal with the sync threshold; and

outputting a sync signal when the input sync signal is greater than the sync threshold.

According to another aspect of the invention, there is provided a circuit for recovering a sync signal from an input sync signal passing through a cable to a display device, the circuit comprising:

integrator for obtaining an average value of the input sync signal during a predetermined time period so as to obtain a sync threshold that is automatically adapted to a polarity of the input sync signal, and

a comparator for comparing the input sync signal with said sync threshold and outputting a sync signal when the input sync signal is greater than the sync threshold.

The invention employs an automatic, signal-dependent sync recovering dynamic threshold to allow full width sync pulses to be recovered from any full, distorted or muted sync signals even when the cable connecting the display monitor to the host unit is as long as 300 m.

### BRIEF DESCRIPTION OF THE DRAWINGS

In order to understand the invention and to see how it may be carried out in practice, embodiments will now be described, by way of non-limiting example only, with reference to the accompanying drawings, in which:

FIGS. 1 1a and 1b show prior art graphical representations of normal and inverted sync pulses;

FIGS. 2, 3 and 4 show graphically the effect on the sync pulse caused by passing through cables of increasing length in prior art configurations;

FIG. 5 shows schematically an electronic circuit according to an embodiment of the invention for recovering horizontal and vertical sync signals regardless of cable length; and

FIG. 6 is a graphical representation of the recovered sync pulses obtained using the circuit of FIG. 5.

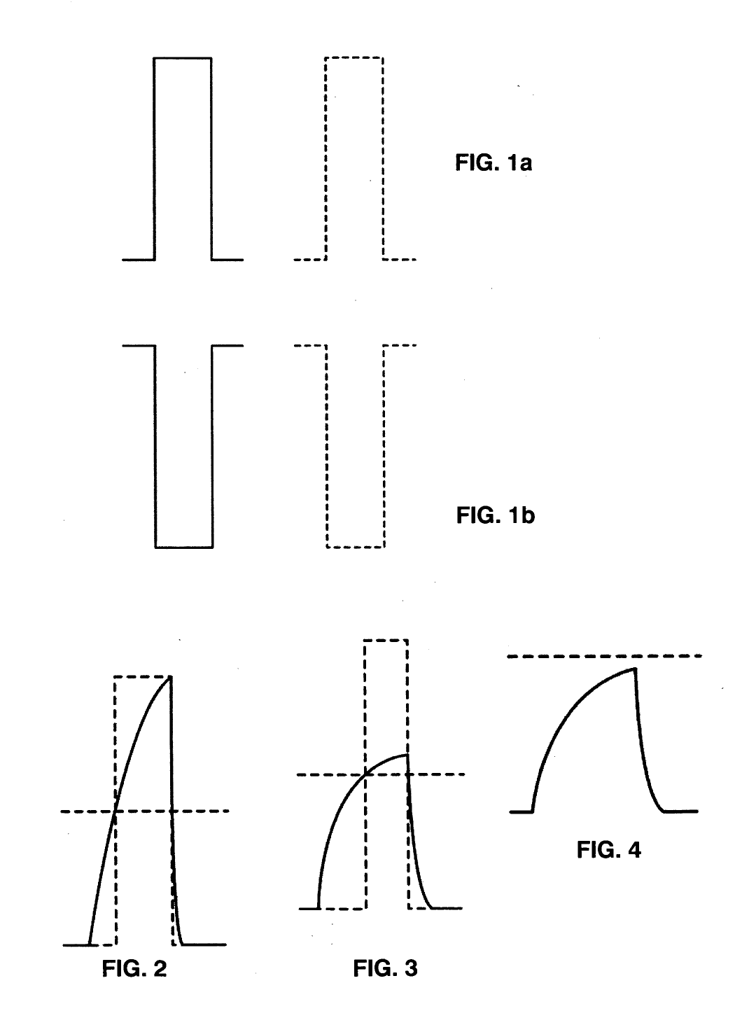

### DETAILED DESCRIPTION OF EMBODIMENTS

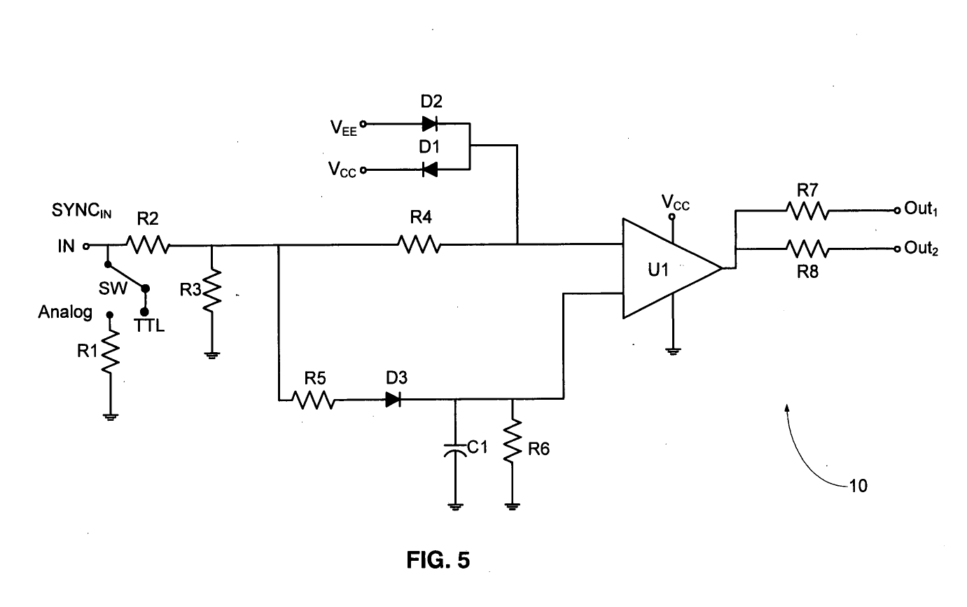

FIG. 5 shows schematically an electronic circuit 10 according to an embodiment of the invention for recovering horizontal and vertical sync signals regardless of cable length. Identical circuits may be used for recovering both horizontal and vertical sync signals, so that in the following description reference to “sync pulse” may be taken to imply either the horizontal or the vertical sync signal.

The circuit comprises an input IN for receiving a TTL sync pulse directly or an analog input sync signal SYNC_{IN} via a first resistor R1 that may optionally be switched into the circuit by means of a selector switch SW. In the case of an analog sync signal that requires a 75Ω load, the input sync signal is 75Ω terminated to ground via the switch SW. In one embodiment reduced to practice, the values of the resistors R1, R2 and R3 were respectively 90.9Ω, 100Ω and 392Ω such that the combined resistance of R1 connected across the series connection of R2 and R3 is approximately 75 ohms.

The input sync signal SYNC_{IN} passes through a voltage divider comprising a second resistor R2 having a first end coupled to the input IN and a second end coupled to the first end of a third resistor R3 whose second end is connected to GND. At the junction of the second and third resistors R2 and R3, the input sync signal is separated into two paths.

One path leads the signal via a fourth resistor R4 into the positive input of an OP-AMP U1. The input is protected against over-voltage by first and second diodes D2 and D3 connected back-to-back in opposite polarities that operate as a clamping diode, which may be realized by an integrated circuit such as BAV99. The clamping diode clamps the input sync signal to VCC and VEE in case of over voltage.

The second path conveys the input sync signal via a fifth resistor R5 to a third rectifier diode D3 such as FDLL4148 that charges a capacitor C1 with its voltage. A sixth resistor R6 serves as a bleeder resistor to maintain the average voltage of the sync signal and eliminate the possibility that the capacitor C1 will become over charged.

The DC voltage at the junction of the capacitor C1 and the sixth resistor R6 is fed to the negative input of the OP-AMP U1 and is used as a reference voltage for the input sync pulse fed to the positive input of the OP-AMP. The OP-AMP U1 acts as a threshold comparator for comparing the level of the input sync signal at its positive input with the reference slicing voltage at its negative input, which constitutes a voltage threshold. If the input sync signal exceeds the threshold voltage, the output recovered sync is now full TTL level (5 V peak-peak) and is sent to the respective sync control circuits of the display monitor. If desired, up to four receivers display monitors can be fed with the recovered sync signal each via a respective output resistor such as R7 and R8.

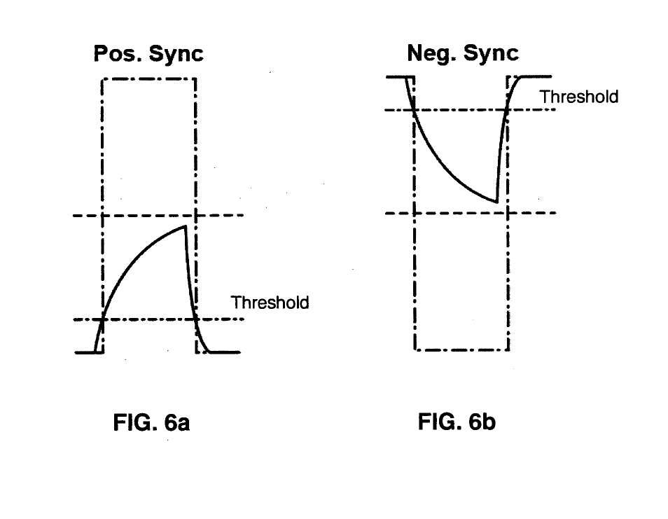

If the sync pulse is positive going as shown in FIG. 6a, the average voltage generated at the junction of the capacitor C1 and the sixth resistor R6 is low, —due to the low duty cycle of the sync pulses and the ratio between the charging resistor R5 and the bleeding resistor R6— so, that the slicing threshold is approximately 700 mV above ground level.

If the sync pulse is a negative going pulse as shown in FIG. 6b, the average voltage generated at the junction of the capacitor C1 and the sixth resistor R6 is high, and the slicing threshold is approximately 700 mV below the highest sync level.

The result is that regardless of the polarity or shape of the input sync signal, once its level rises above 700 mV, the circuit 10 dynamically detects and recreates a full width and full TTL level sync at the output.

It should be noted that the threshold of 700 mV is selected as a compromise between the desirability of increasing the length of cable over which the sync signals can be recovered, while reducing sensitivity of the control system to noise. Thus, the smaller the threshold, the longer is the cable that may be used while allowing recovery but the greater the risk that noise will be interpreted as a sync signal. The threshold of 700 mV is thus merely an example of a signal level that is of sufficient amplitude to allow signal synchronization while being distinguishable from a predetermined upper noise level. Different types of display monitor employ sync signals of different amplitudes and as display devices evolve it is, in any case, likely that sync signals of lower amplitude will be feasible and that better noise suppression may be utilized such that the threshold may be reduced below 700 mV.

For the sake of completeness, it should be noted that in an actual embodiment reduced to practice, the values of the components were as follows:

| Component | Value |
|---|---|
| R1 | 90.9Ω |
| R2 | 100Ω |
| R3 | 392Ω |
| R4 | 1KΩ |
| R5 | 10KΩ |
| R6 | 100KΩ |
| R7, R8 | 51Ω |
| C1 | l μF |

It will be appreciated that these values are given by way of example only and changes can be made to the circuit without departing from the scope of the invention as changed.

It will also be understood that the invention is applicable to all types of raster scan display, such as cathode ray tube (CRT), LCD or Plasma.

1. A method for recovering a sync signal from an input sync signal passing through a cable to a display device, the method comprising:
obtaining a weighted reference value of the input sync signal during a predetermined time period so as to obtain a sync threshold that is automatically adapted to a polarity of the input sync signal;
comparing the input sync signal with the sync threshold; and outputting a sync signal when the input sync signal is greater than the sync threshold for a positive going sync signal and when the input sync signal is less than the sync threshold for a negative going sync signal.

2. The method according to claim 1, wherein the predetermined time period is selected to ensure that the sync threshold is of sufficient amplitude to allow synchronization while being distinguishable from a predetermined upper noise level.

3. A circuit for recovering a sync signal from an input sync signal passing through a cable to display device, the circuit comprising:
a weighted integrator for obtaining a sync threshold that is automatically adapted to a polarity of the input sync signal, and
a comparator for comparing the input sync signal with said sync threshold and outputting a sync signal when the input sync signal is greater than the sync threshold.

4. The circuit according to claim 3, wherein the weighted integrator includes a bleeder resistor connected in parallel with the capacitor so that the capacitor and the bleeder resistor have a time constant that is configured to ensure that the sync threshold is of sufficient amplitude to allow synchronization while being distinguishable from a predetermined upper noise level.

5. The circuit according to claim 3, further including a selector switch for selectably switching between a TTL sync level and an analog sync level.

6. The circuit according to claim, comprising:
an input coupled to ground via a voltage divider comprising a pair of resistors having a common junction fed to a first input of the comparator, said weighted integrator including
a rectifier coupled via a resistor for feeding a rectified portion of the input sync signal to a peak detector having an output fed to a second input of the comparator, and
at least one output coupled to an output of the comparator for feeding a recovered TTL sync signal to a respective display monitor.

7. The circuit according to claim 6, further comprising a clamping diode for clamping the input sync signal to VCC and VEE in case of over voltage.

8. The circuit according to claim 3, wherein the weighted integrator includes a capacitor and a pair of resistors such that an average voltage across the capacitor is a function of a duty cycle of the incoming sync signal and a ratio of said resistors.
